(19) United States
(12) Patent Application Publication
(10) Pub. No.: US 2023/0260788 A1
(43) Pub. Date: Aug. 17, 2023

(54) CARBON-NITRIDE-CARBON HARDMASK LAYER

(71) Applicant: Intel Corporation, Santa Clara, CA (US)

(72) Inventors: Huy Cao, Albuquerque, NM (US); Hong Li, Albuquerque, NM (US); Jian Jiao, Albuquerque, NM (US); Xiandong Yang, Albuquerque, NM (US); Honore Djieutedjeu, Rio Rancho, NM (US); Jean Claude Chokomakoua, Rio Rancho, NM (US); Ram Raju, Albuquerque, NM (US); Bharat Krishnan, Albuquerque, NM (US)

(73) Assignee: Intel Corporation, Santa Clara, CA (US)

(21) Appl. No.: 17/671,101

(22) Filed: Feb. 14, 2022

(51) Int. Cl. H01L 21/033; C01B 21/082

(52) U.S. Cl. CPC H01L 21/0332; H01L 21/0337; C01B 21/082; H01L 27/2481

(57) ABSTRACT

An embodiment of an apparatus may include a substrate and a semiconductor structure disposed on the substrate, where the semiconductor structure comprises a plurality of layers of material and where at least one layer of the plurality of layers of material comprises carbon-nitride-carbon (CNC). Other embodiments are disclosed and claimed.

### BACKGROUND

In the field of semiconductor fabrication, a hardmask refers to material used in place of polymers or other soft resist material as an etch mask. A pattern defined using a soft mask may be more rapidly degraded during plasma etching because polymers tend to be etched more easily by various reactive gases. Hardmasks may be particularly beneficial when the material being etched is itself a polymeric material. Hardmasks are also useful for etching deep, high aspect ratio features. Example hardmask materials include silicon dioxide, silicon carbide, amorphous carbon, titanium nitride, and tantalum nitride.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is an illustrative diagram of an example of an apparatus according to an embodiment;

FIGS. 2A to 2C are illustrative diagrams of an example of a method according to an embodiment;

FIG. 3 is a block diagram of an example of a system according to an embodiment;

FIG. 4 is an illustrative diagram of an example of a three-dimensional memory device according to an embodiment;

FIG. 5 is an illustrative diagram of an example of a process according to an embodiment;

FIG. 6 is a block diagram of an example of a computing system according to an embodiment.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

While the following description sets forth various implementations that may be manifested in architectures such as system-on-a-chip (SoC) architectures for example, implementation of the techniques and/or arrangements described herein are not restricted to particular architectures and/or computing systems and may be implemented by any architecture and/or computing system for similar purposes. For instance, various architectures employing, for example, multiple integrated circuit (IC) chips and/or packages, and/or various computing devices and/or consumer electronic (CE) devices such as set top boxes, smartphones, etc., may implement the techniques and/or arrangements described herein. Further, while the following description may set forth numerous specific details such as logic implementations, types and interrelationships of system components, logic partitioning/integration choices, etc., claimed subject matter may be practiced without such specific details. In other instances, some material such as, for example, control structures and full software instruction sequences, may not be shown in detail in order not to obscure the material disclosed herein.

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit.

Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, magnetic or fluidic connection between the things that are connected or an indirect connection, through one or more passive or active intermediary devices.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and it is understood that recitations of “top”, “bottom”, “above” and “below” refer to relative positions in the z-dimension with the usual meaning. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile” and “plan” correspond to orthogonal planes within a cartesian coordinate system. Thus, cross-sectional and profile views are taken in the x-z plane, and plan views are taken in the x-y plane. Typically, profile views in the x-z plane are cross-sectional views. Where appropriate, drawings are labeled with axes to indicate the orientation of the figure.

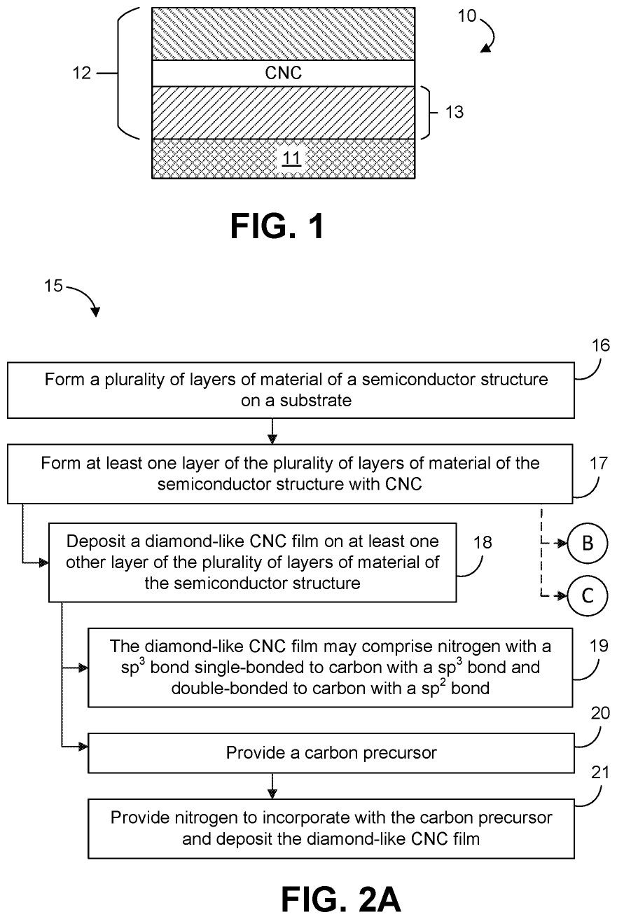

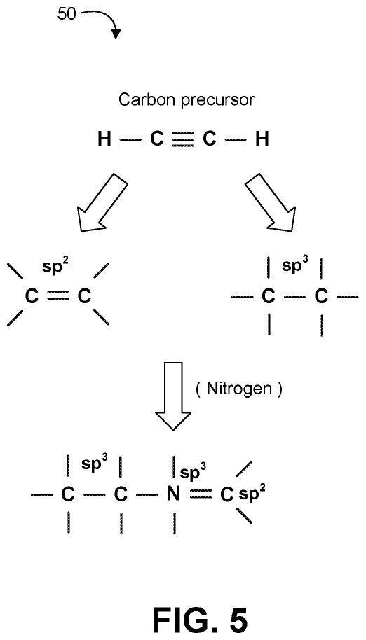

With reference to FIG. 1, an embodiment of an apparatus 10 may include a substrate 11 and a semiconductor structure 12 disposed on the substrate 13. The semiconductor structure 12 may comprise a plurality of layers of material and at least one layer of the plurality of layers of material comprises carbon-nitride-carbon (CNC). In some embodiments, the CNC may comprise diamond-like CNC. For example, the CNC may comprise nitrogen with a sp³ bond single-bonded to carbon with a sp³ bond and double-bonded to carbon with a sp² bond (e.g., see FIG. 5). Although illustrated as a continuous layer of CNC material, those skilled in the art will appreciate that in practical implementations the layer of CNC material may be patterned and/or may include discontinuities and/or voids in the layer of CNC material. For example, in some embodiments, the layer of CNC material may be utilized as a hardmask layer.

In some embodiments, the plurality of layers of the semiconductor structure 12 may comprise one or more layers 13 of a logic circuit, and the at least one layer of the plurality of layers of material that comprises CNC may be disposed on the one or more layers 13 of the logic circuit. Alternatively, or additionally, the one or more layers 13 may comprise a memory array with the at least one layer of the plurality of layers of material that comprises CNC disposed on the one or more layers of the memory array. In some embodiments, the memory array may comprise a three-dimensional (3D) memory array.

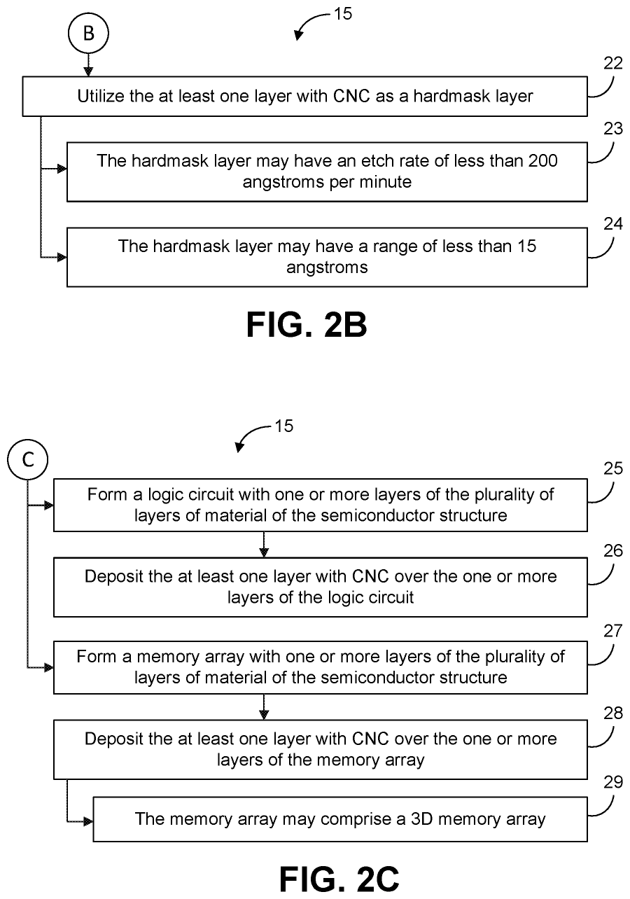

With reference to FIGS. 2A to 2C, an embodiment of a method 15 may include forming a plurality of layers of material of a semiconductor structure on a substrate at box 16, and forming at least one layer of the plurality of layers of material of the semiconductor structure with CNC at box 17. In some embodiments, forming the at least one layer of the plurality of layers of material with CNC may further comprise depositing a diamond-like CNC film on at least one other layer of the plurality of layers of material of the semiconductor structure at box 18. For example, the diamond-like CNC film may comprise nitrogen with a sp³ bond single-bonded to carbon with a sp³ bond and double-bonded to carbon with a sp² bond at box 19. In some embodiments, depositing the diamond-like CNC film may further comprise providing a carbon precursor at box 20, and providing nitrogen to incorporate with the carbon precursor and deposit the diamond-like CNC film at box 21.

Some embodiments of the method 15 may further include utilizing the at least one layer with CNC as a hardmask layer at box 22. For example, the hardmask layer may have an etch rate of less than 200 angstroms per minute at box 23, and the hardmask layer may have a range of less than 15 angstroms at box 24.

Some embodiments of the method 15 may further include forming a logic circuit with one or more layers of the plurality of layers of material of the semiconductor structure at box 25, and depositing the at least one layer with CNC over the one or more layers of the logic circuit at box 26. Alternatively, or additionally, the method 15 may further include forming a memory array with one or more layers of the plurality of layers of material of the semiconductor structure at box 27, and depositing the at least one layer with CNC over the one or more layers of the memory array at box 28. For example, the memory array may comprise a 3D memory array at box 29.

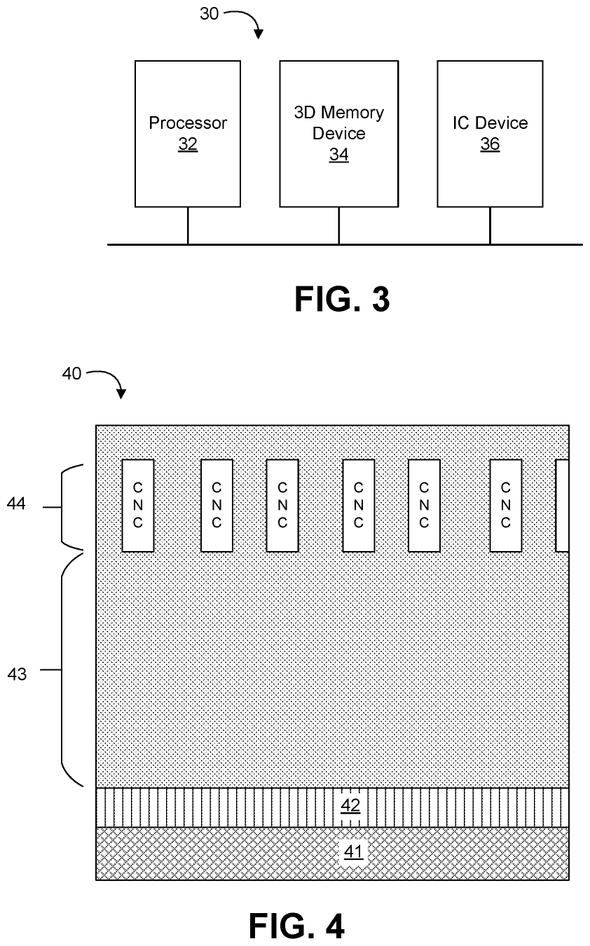

With reference to FIG. 3, an embodiment of a system 30 may include a processor 32 and a 3D memory device 34 coupled to the processor 32. The 3D memory device 34 may include a substrate, a 3D memory array formed on the substrate, and CNC formed on the 3D memory array. In some embodiments, the CNC comprises diamond-like CNC. For example, the CNC may comprise nitrogen with a sp³ bond single-bonded to carbon with a sp³ bond and double-bonded to carbon with a sp² bond. Some embodiments of the system 30 may further include an integrated circuit (IC) device 36 coupled to one or more of the processor 32 and the 3D memory device 34, where the IC device 36 includes a substrate, a logic circuit formed on the substrate, and CNC formed on the logic circuit.

Some embodiments provide a diamond CNC hardmask for a memory array. In some semiconductor fabrication processes, a conventional carbon hardmask film may impose an undesirably high compressive stress on the substrate (e.g., which may cause a positive bow on the substrate). With the conventional carbon hardmask, additional process steps may be needed to reduce the stress on the substrate and/or to improve etch resistance and/or selectivity. Additional process steps increase the costs involved with the semiconductor fabrication process.

Some embodiments provide technology for a diamond (e.g., or diamond-like) CNC hardmask. Advantageously, embodiments of a diamond-like CNC hardmask may improve one or more of film stress, the subsequent etch processing selectivity, and/or films stoichiometry throughout the film/bulk material and therefore may enable fewer steps in a semiconductor fabrication process. Some embodiments may involve incorporating nitride atoms into the carbon film to form a stable carbon-nitride-carbon bond that advantageously improves the stress of the material to be less compressive. In addition, embodiments of the material may become more stable with the incorporation of the nitrogen reacting with the carbon to create more sp³ bonds in the material. Embodiments of a diamond-like CNC hardmask may also improve etch selectivity and uniformity, which may improve downstream processes and/or electrical characteristics of the resulting semiconductor devices.

With reference to FIG. 4, an embodiment of a 3D memory device 40 includes a substrate 41 with one or more adhesion layers 42 formed thereon. A 3D memory array 43 is formed on the adhesion layer(s) 42, and a diamond-like CNC hardmask 44 is formed on the 3D memory array 43. For example, the diamond-like CNC hardmask 44 may comprise nitrogen with a sp³ bond single-bonded to carbon with a sp³ bond and double-bonded to carbon with a sp² bond (e.g., see FIG. 5). For example, the 3D memory array 43 may be a 3D crosspoint memory array, or other byte addressable write-in-place nonvolatile 3D memory array. In some embodiments, the 3D memory array 43 may use chalcogenide glass, single or multi-level Phase Change Memory (PCM), a resistive memory, nanowire memory, ferroelectric transistor RAM (FeTRAM), anti-ferroelectric memory, magnetoresistive RAM (MRAM) memory that incorporates memristor technology, resistive memory including the metal oxide base, the oxygen vacancy base and the conductive bridge RAM (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The 3D memory device 40 may refer to the die itself and/or to a packaged memory product. In particular embodiments, a memory component with non-volatile memory may comply with one or more standards promulgated by the JEDEC, or other suitable standard (the JEDEC standards cited herein are available at jedec.org).

With reference to FIG. 5, an embodiment of a process 50 for depositing a diamond-like CNC film on a substrate (e.g., a semiconductor wafer) includes placing the substrate in a plasma-enhanced chemical vapor deposition (PECVD) chamber (e.g., secured to a chuck). The process 50 then includes introducing a carbon precursor into the PECVD chamber. For a carbon precursor of C₂H₂, for example, the triple bonded carbon molecules are bonded with hydrogen atoms to provide a stable precursor as an ideal gas for the process 50. As the carbon precursor is introduced into the PECVD chamber, the plasma disassociates the precursor bonds into derivatives of the precursor to form two distinct chemical precursors for the final film. The process 50 then includes introducing nitrogen into the PECVD chamber. The incorporation of the nitrogen into the chamber at the same time as the carbon precursor rearranges the atoms in such a way that associates the nitrogen into the carbon to form a C₂NH₉ structure. Then, the material will catenate to form long hybridization chains of the final diamond-like CNC film onto the substrate.

Advantageously, embodiments of a CNC film may be measurably more stable than conventional carbon films due to the bonding structure of the CNC film. Embodiments of a CNC film may also exhibit measurably less stress and more uniformity throughout the bulk material, as compared to conventional carbon films, making embodiments of the CNC film a well-suited flat film from an etch perspective and a uniformity perspective. Embodiments of the CNC film may be both uniform in film composition and well behaved when the CNC film is subjected to a harsh etching environment (e.g., the etch rate may be lower and uniformity may be superior as compared to conventional carbon films). Embodiments of the CNC film may exhibit improved films stoichiometry as compared to conventional carbon films, with stable concentrations of nitrogen (e.g., a relatively flat secondary ion mass spectrometry (SIMS) profile through a wider range of depths). Embodiments of the CNC film may exhibit etch resistance/selectivity to SiN of less than 200 angstroms per minute with a range of less than 15 angstroms, and etch uniformity may be substantially improved as compared to conventional carbon films.

The technology discussed herein may be provided in various computing systems (e.g., including a non-mobile computing device such as a desktop, workstation, server, rack system, etc., a mobile computing device such as a smartphone, tablet, Ultra-Mobile Personal Computer (UMPC), laptop computer, ULTRABOOK computing device, smart watch, smart glasses, smart bracelet, etc., and/or a client/edge device such as an Internet-of-Things (IoT) device (e.g., a sensor, a camera, etc.)).

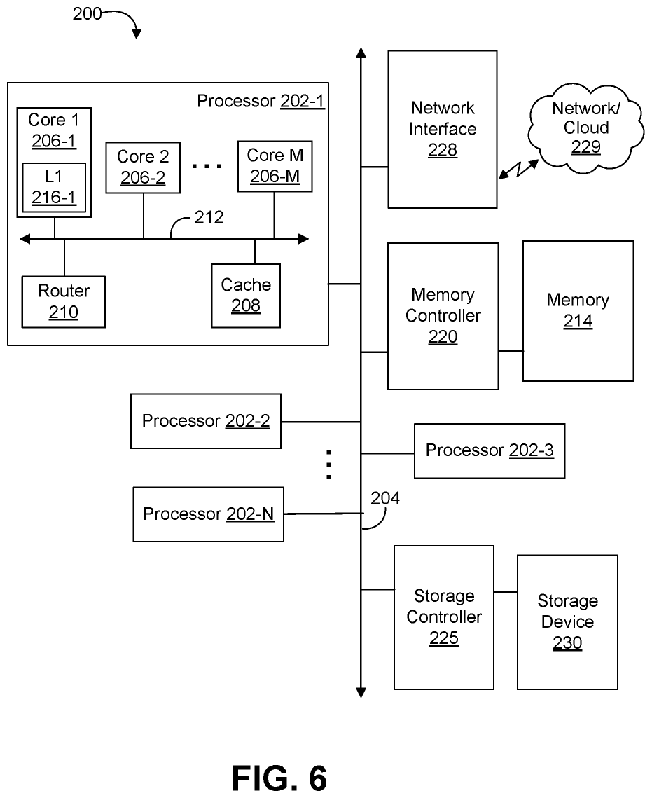

Turning now to FIG. 6, an embodiment of a computing system 200 may include one or more processors 202-1 through 202-N (generally referred to herein as “processors 202” or “processor 202”). The processors 202 may communicate via an interconnection or bus 204. Each processor 202 may include various components some of which are only discussed with reference to processor 202-1 for clarity. Accordingly, each of the remaining processors 202-2 through 202-N may include the same or similar components discussed with reference to the processor 202-1.

In some embodiments, the processor 202-1 may include one or more processor cores 206-1 through 206-M (referred to herein as “cores 206,” or more generally as “core 206”), a cache 208 (which may be a shared cache or a private cache in various embodiments), and/or a router 210. The processor cores 206 may be implemented on a single integrated circuit (IC) chip. Moreover, the chip may include one or more shared and/or private caches (such as cache 208), buses or interconnections (such as a bus or interconnection 212), memory controllers, or other components.

In some embodiments, the router 210 may be used to communicate between various components of the processor 202-1 and/or system 200. Moreover, the processor 202-1 may include more than one router 210. Furthermore, the multitude of routers 210 may be in communication to enable data routing between various components inside or outside of the processor 202-1.

The cache 208 may store data (e.g., including instructions) that is utilized by one or more components of the processor 202-1, such as the cores 206. For example, the cache 208 may locally cache data stored in a memory 214 for faster access by the components of the processor 202. As shown in FIG. 6, the memory 214 may be in communication with the processors 202 via the interconnection 204. In some embodiments, the cache 208 (that may be shared) may have various levels, for example, the cache 208 may be a mid-level cache and/or a last-level cache (LLC). Also, each of the cores 206 may include a level 1 (L1) cache (216-1) (generally referred to herein as “L1 cache 216”). Various components of the processor 202-1 may communicate with the cache 208 directly, through a bus (e.g., the bus 212), and/or a memory controller or hub.

As shown in FIG. 6, memory 214 may be coupled to other components of system 200 through a memory controller 220. Memory 214 may include volatile memory and may be interchangeably referred to as main memory or system memory. Even though the memory controller 220 is shown to be coupled between the interconnection 204 and the memory 214, the memory controller 220 may be located elsewhere in system 200. For example, memory controller 220 or portions of it may be provided within one of the processors 202 in some embodiments. Alternatively, memory 214 may include byte-addressable non-volatile memory such as INTEL OPTANE technology.

The system 200 may communicate with other devices/systems/networks via a network interface 228 (e.g., which is in communication with a computer network and/or the cloud 229 via a wired or wireless interface). For example, the network interface 228 may include an antenna (not shown) to wirelessly (e.g., via an Institute of Electrical and Electronics Engineers (IEEE) 802.11 interface (including IEEE 802.11a/b/g/n/ac, etc.), cellular interface, 3G, 4G, LTE, BLUETOOTH, etc.) communicate with the network/cloud 229.

System 200 may also include a storage device such as a storage device 230 coupled to the interconnect 204 via storage controller 225. Hence, storage controller 225 may control access by various components of system 200 to the storage device 230. Furthermore, even though storage controller 225 is shown to be directly coupled to the interconnection 204 in FIG. 10, storage controller 225 can alternatively communicate via a storage bus/interconnect (such as the SATA (Serial Advanced Technology Attachment) bus, Peripheral Component Interconnect (PCI) (or PCI EXPRESS (PCIe) interface), NVM EXPRESS (NVMe), Serial Attached SCSI (SAS), Fiber Channel, etc.) with one or more other components of system 200 (for example where the storage bus is coupled to interconnect 204 via some other logic like a bus bridge, chipset, etc.) Additionally, storage controller 225 may be incorporated into memory controller logic or provided on a same integrated circuit (IC) device in various embodiments (e.g., on the same circuit board device as the storage device 230 or in the same enclosure as the storage device 230).

Furthermore, storage controller 225 and/or storage device 230 may be coupled to one or more sensors (not shown) to receive information (e.g., in the form of one or more bits or signals) to indicate the status of or values detected by the one or more sensors. These sensor(s) may be provided proximate to components of system 200 (or other computing systems discussed herein), including the cores 206, interconnections 204 or 212, components outside of the processor 202, storage device 230, SSD bus, SATA bus, storage controller 225, etc., to sense variations in various factors affecting power/thermal behavior of the system/platform, such as temperature, operating frequency, operating voltage, power consumption, and/or inter-core communication activity, etc.

Any of the memory devices, storage devices, and/or logic devices in the system 200 may include CNC film material, as described herein (e.g., utilized as a hardmask layer). In particular, the system 200 may include the processors 202 and a 3D memory device (e.g., memory 214, storage device 230, etc.) coupled to the processors 102, where the 3D memory device includes a substrate, a 3D memory array formed on the substrate, and CNC formed on the 3D memory array. In some embodiments of the system 200, any of the other IC devices (e.g., the processors, the controllers, etc.) may include a substrate, a logic circuit formed on the substrate, and CNC formed on the logic circuit. In some embodiments, the CNC comprises diamond-like CNC. For example, the CNC may comprise nitrogen with a sp³ bond single-bonded to carbon with a sp³ bond and double-bonded to carbon with a sp² bond.

### Additional Notes and Examples

Example 1 includes an apparatus, comprising a substrate, and a semiconductor structure disposed on the substrate, wherein the semiconductor structure comprises a plurality of layers of material and wherein at least one layer of the plurality of layers of material comprises carbon-nitride-carbon (CNC).

Example 2 includes the apparatus of Example 1, wherein the CNC comprises diamond-like CNC.

Example 3 includes the apparatus of Example 1, wherein the CNC comprises nitrogen with a sp³ bond single-bonded to carbon with a sp³ bond and double-bonded to carbon with a sp² bond.

Example 4 includes the apparatus of any of Examples 1 to 3, wherein the plurality of layers of the semiconductor structure comprises one or more layers of a logic circuit, and wherein the at least one layer of the plurality of layers of material that comprises CNC is disposed on the one or more layers of the logic circuit.

Example 5 includes the apparatus of any of Examples 1 to 4, wherein the plurality of layers of the semiconductor structure comprises one or more layers of a memory array, and wherein the at least one layer of the plurality of layers of material that comprises CNC is disposed on the one or more layers of the memory array.

Example 6 includes the apparatus of Example 5, wherein the memory array comprises a three-dimensional memory array.

Example 7 includes a method, comprising forming a plurality of layers of material of a semiconductor structure on a substrate, and forming at least one layer of the plurality of layers of material of the semiconductor structure with carbon-nitride-carbon (CNC).

Example 8 includes the method of Example 7, wherein forming the at least one layer of the plurality of layers of material with CNC further comprises depositing a diamond-like CNC film on at least one other layer of the plurality of layers of material of the semiconductor structure.

Example 9 includes the method of Example 8, wherein the diamond-like CNC film comprises nitrogen with a sp³ bond single-bonded to carbon with a sp³ bond and double-bonded to carbon with a sp² bond.

Example 10 includes the method of any of Examples 8 to 9, wherein depositing the diamond-like CNC film further comprises providing a carbon precursor, and providing nitrogen to incorporate with the carbon precursor and deposit the diamond-like CNC film.

Example 11 includes the method of any of Examples 7 to 10, further comprising utilizing the at least one layer with CNC as a hardmask layer.

Example 12 includes the method of Example 11, wherein the hardmask layer has an etch rate of less than 200 angstroms per minute.

Example 13 includes the method of Example 12, wherein the hardmask layer has a range of less than 15 angstroms.

Example 14 includes the method of any of Examples 7 to 13, further comprising forming a logic circuit with one or more layers of the plurality of layers of material of the semiconductor structure, and depositing the at least one layer with CNC over the one or more layers of the logic circuit.

Example 15 includes the method of any of Examples 7 to 14, further comprising forming a memory array with one or more layers of the plurality of layers of material of the semiconductor structure, and depositing the at least one layer with CNC over the one or more layers of the memory array.

Example 16 includes the method of Example 15, wherein the memory array comprises a three-dimensional memory array.

Example 17 includes a system, comprising a processor and a three-dimensional (3D) memory device coupled to the processor, wherein the 3D memory device includes a substrate, a 3D memory array formed on the substrate, and carbon-nitride-carbon (CNC) formed on the 3D memory array.

Example 18 includes the system of Example 17, wherein the CNC comprises diamond-like CNC.

Example 19 includes the system of Example 17, wherein the CNC comprises nitrogen with a sp³ bond single-bonded to carbon with a sp³ bond and double-bonded to carbon with a sp² bond.

Example 20 includes the system of Example 19, further comprising an integrated circuit (IC) device coupled to one or more of the processor and the 3D memory device, wherein the IC device includes a substrate, a logic circuit formed on the substrate, and CNC formed on the logic circuit.

Example 21 includes a semiconductor fabrication apparatus, comprising means for forming a plurality of layers of material of a semiconductor structure on a substrate, and means for forming at least one layer of the plurality of layers of material of the semiconductor structure with carbon-nitride-carbon (CNC).

Example 22 includes the apparatus of Example 21, wherein the means for forming the at least one layer of the plurality of layers of material with CNC further comprises means for depositing a diamond-like CNC film on at least one other layer of the plurality of layers of material of the semiconductor structure.

Example 23 includes the apparatus of Example 22, wherein the diamond-like CNC film comprises nitrogen with a sp³ bond single-bonded to carbon with a sp³ bond and double-bonded to carbon with a sp² bond.

Example 24 includes the apparatus of any of Examples 22 to 23, wherein the means for depositing the diamond-like CNC film further comprises means for providing a carbon precursor, and means for providing nitrogen to incorporate with the carbon precursor and deposit the diamond-like CNC film.

Example 25 includes the apparatus of any of Examples 21 to 24, further comprising means for utilizing the at least one layer with CNC as a hardmask layer.

Example 26 includes the apparatus of Example 25, wherein the hardmask layer has an etch rate of less than 200 angstroms per minute.

Example 27 includes the apparatus of Example 26, wherein the hardmask layer has a range of less than 15 angstroms.

Example 28 includes the apparatus of any of Examples 21 to 27, further comprising means for forming a logic circuit with one or more layers of the plurality of layers of material of the semiconductor structure, and means for depositing the at least one layer with CNC over the one or more layers of the logic circuit.

Example 29 includes the apparatus of any of Examples 21 to 28, further comprising means for forming a memory array with one or more layers of the plurality of layers of material of the semiconductor structure, and means for depositing the at least one layer with CNC over the one or more layers of the memory array.

Example 30 includes the apparatus of Example 29, wherein the memory array comprises a three-dimensional memory array.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrase “one or more of A, B, and C” and the phrase “one or more of A, B, or C” both may mean A; B; C; A and B; A and C; B and C; or A, B and C. Various components of the systems described herein may be implemented in software, firmware, and/or hardware and/or any combination thereof. For example, various components of the systems or devices discussed herein may be provided, at least in part, by hardware of a computing SoC such as may be found in a computing system such as, for example, a smart phone. Those skilled in the art may recognize that systems described herein may include additional components that have not been depicted in the corresponding figures. For example, the systems discussed herein may include additional components such as bit stream multiplexer or de-multiplexer modules and the like that have not been depicted in the interest of clarity.

While implementation of the example processes discussed herein may include the undertaking of all operations shown in the order illustrated, the present disclosure is not limited in this regard and, in various examples, implementation of the example processes herein may include only a subset of the operations shown, operations performed in a different order than illustrated, or additional operations.

In addition, any one or more of the operations discussed herein may be undertaken in response to instructions provided by one or more computer program products. Such program products may include signal bearing media providing instructions that, when executed by, for example, a processor, may provide the functionality described herein. The computer program products may be provided in any form of one or more machine-readable media. Thus, for example, a processor including one or more graphics processing unit(s) or processor core(s) may undertake one or more of the blocks of the example processes herein in response to program code and/or instructions or instruction sets conveyed to the processor by one or more machine-readable media. In general, a machine-readable medium may convey software in the form of program code and/or instructions or instruction sets that may cause any of the devices and/or systems described herein to implement at least portions of the operations discussed herein and/or any portions the devices, systems, or any module or component as discussed herein.

As used in any implementation described herein, the term “module” refers to any combination of software logic, firmware logic, hardware logic, and/or circuitry configured to provide the functionality described herein. The software may be embodied as a software package, code and/or instruction set or instructions, and “hardware”, as used in any implementation described herein, may include, for example, singly or in any combination, hardwired circuitry, programmable circuitry, state machine circuitry, fixed function circuitry, execution unit circuitry, and/or firmware that stores instructions executed by programmable circuitry. The modules may, collectively or individually, be embodied as circuitry that forms part of a larger system, for example, an integrated circuit (IC), system on-chip (SoC), and so forth.

Various embodiments may be implemented using hardware elements, software elements, or a combination of both. Examples of hardware elements may include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, chip sets, and so forth. Examples of software may include software components, programs, applications, computer programs, application programs, system programs, machine programs, operating system software, middleware, firmware, software modules, routines, subroutines, functions, methods, procedures, software interfaces, application program interfaces (API), instruction sets, computing code, computer code, code segments, computer code segments, words, values, symbols, or any combination thereof. Determining whether an embodiment is implemented using hardware elements and/or software elements may vary in accordance with any number of factors, such as desired computational rate, power levels, heat tolerances, processing cycle budget, input data rates, output data rates, memory resources, data bus speeds and other design or performance constraints.

One or more aspects of at least one embodiment may be implemented by representative instructions stored on a machine-readable medium which represents various logic within the processor, which when read by a machine causes the machine to fabricate logic to perform the techniques described herein. Such representations, known as IP cores may be stored on a tangible, machine readable medium and supplied to various customers or manufacturing facilities to load into the fabrication machines that actually make the logic or processor.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the embodiments are not limited to the embodiments so described, but can be practiced with modification and alteration without departing from the scope of the appended claims. For example, the above embodiments may include specific combination of features. However, the above embodiments are not limited in this regard and, in various implementations, the above embodiments may include the undertaking only a subset of such features, undertaking a different order of such features, undertaking a different combination of such features, and/or undertaking additional features than those features explicitly listed. The scope of the embodiments should, therefore, be determined with reference to the appended claims, along with the full scope of equivalents to which such claims are entitled.

What is claimed is:

1. An apparatus, comprising:
a substrate; and
a semiconductor structure disposed on the substrate, wherein the semiconductor structure comprises a plurality of layers of material and wherein at least one layer of the plurality of layers of material comprises carbon-nitride-carbon (CNC).

2. The apparatus of claim 1, wherein the CNC comprises diamond-like CNC.

3. The apparatus of claim 1, wherein the CNC comprises nitrogen with a sp³ bond single-bonded to carbon with a sp³ bond and double-bonded to carbon with a sp² bond.

4. The apparatus of claim 1, wherein the plurality of layers of the semiconductor structure comprises one or more layers of a logic circuit, and wherein the at least one layer of the plurality of layers of material that comprises CNC is disposed on the one or more layers of the logic circuit.

5. The apparatus of claim 1, wherein the plurality of layers of the semiconductor structure comprises one or more layers of a memory array, and wherein the at least one layer of the plurality of layers of material that comprises CNC is disposed on the one or more layers of the memory array.

6. The apparatus of claim 5, wherein the memory array comprises a three-dimensional memory array.

7. A method, comprising:
forming a plurality of layers of material of a semiconductor structure on a substrate; and
forming at least one layer of the plurality of layers of material of the semiconductor structure with carbon-nitride-carbon (CNC).

8. The method of claim 7, wherein forming the at least one layer of the plurality of layers of material with CNC further comprises:
depositing a diamond-like CNC film on at least one other layer of the plurality of layers of material of the semiconductor structure.

9. The method of claim 8, wherein the diamond-like CNC film comprises nitrogen with a sp³ bond single-bonded to carbon with a sp³ bond and double-bonded to carbon with a sp² bond.

10. The method of claim 8, wherein depositing the diamond-like CNC film further comprises:
providing a carbon precursor; and
providing nitrogen to incorporate with the carbon precursor and deposit the diamond-like CNC film.

11. The method of claim 7, further comprising:
utilizing the at least one layer with CNC as a hardmask layer.

12. The method of claim 11, wherein the hardmask layer has an etch rate of less than 200 angstroms per minute.

13. The method of claim 12, wherein the hardmask layer has a range of less than 15 angstroms.

14. The method of claim 7, further comprising:
forming a logic circuit with one or more layers of the plurality of layers of material of the semiconductor structure; and
depositing the at least one layer with CNC over the one or more layers of the logic circuit.

15. The method of claim 7, further comprising:
forming a memory array with one or more layers of the plurality of layers of material of the semiconductor structure; and
depositing the at least one layer with CNC over the one or more layers of the memory array.

16. The method of claim 15, wherein the memory array comprises a three-dimensional memory array.

17. A system, comprising:
a processor and a three-dimensional (3D) memory device coupled to the processor, wherein the 3D memory device includes:
a substrate;
a 3D memory array formed on the substrate; and
carbon-nitride-carbon (CNC) formed on the 3D memory array.

18. The system of claim 17, wherein the CNC comprises diamond-like CNC.

19. The system of claim 17, wherein the CNC comprises nitrogen with a sp³ bond single-bonded to carbon with a sp³ bond and double-bonded to carbon with a sp² bond.

20. The system of claim 19, further comprising:
an integrated circuit (IC) device coupled to one or more of the processor and the 3D memory device, wherein the IC device includes:
a substrate;
a logic circuit formed on the substrate; and
CNC formed on the logic circuit.
